(19) United States
(12) Patent Application Publication
(10) Pub. No.: US 2024/0178313 A1
(43) Pub. Date: May 30, 2024

(54) ENHANCED GAN HEMT RADIO-FREQUENCY DEVICE AND MANUFACTURING METHOD THEREOF

(71) Applicant: SOUTH CHINA UNIVERSITY OF TECHNOLOGY, Guangzhou (CN)

(72) Inventors: Guoqiang LI, Guangzhou (CN); Nengtao WU, Guangzhou (CN); Zhiheng XING, Guangzhou (CN); Shanjie LI, Guangzhou (CN); Fanyi ZENG, Guangzhou (CN); Ling LUO, Guangzhou (CN)

(73) Assignee: SOUTH CHINA UNIVERSITY OF TECHNOLOGY, Guangzhou (CN)

(21) Appl. No.: 18/281,790

(22) PCT Filed: Sep. 23, 2022
(86) PCT No.: PCT/CN2022/120938

§ 371 Date: Sep. 13, 2023

(30) Foreign Application Priority Data
Dec. 6, 2021 (CN) 202111475724.8

(51) Int. Cl. H01L 29/778; H01L 21/225; H01L 29/20; H01L 29/66

(52) U.S. Cl. CPC H01L 29/7787; H01L 21/2258; H01L 29/2003; H01L 29/66462

(57) ABSTRACT

An enhanced GaN high electron mobility transistor (HEMT) radio-frequency device and a manufacturing method thereof are provided. The enhanced GaN HEMT radio-frequency device includes a substrate, a first AlN interposed layer, a GaN buffer layer, a GaN trench layer, a second AlN interposed layer, an AlGaN barrier layer, a p-AlGaN layer, a metal drain electrode, a metal source electrode, and a metal gate electrode. Under an extremely high vacuum degree, metal Mg is doped and diffused to the AlGaN layer to form the p-AlGaN layer, and the metal Mg further forms a p-n junction with the undoped AlGaN layer, thereby depleting a two-dimensional electron gas (2DEG) under the gate. A HfO₂ layer covers the metal Mg to prevent oxidation of the metal Mg.

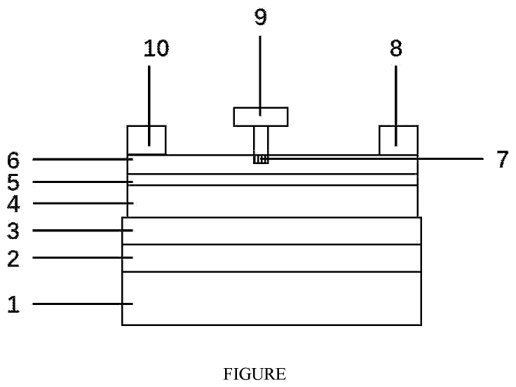

### CROSS REFERENCE TO THE RELATED APPLICATIONS

This application is the national phase entry of International Application No. PCT/CN2022/120938, filed on Sep. 23, 2022, which is based upon and claims priority to Chinese Patent Application No. 202111475724.8, filed on Dec. 6, 2021, the entire contents of which are incorporated herein by reference.

### TECHNICAL FIELD

The present disclosure belongs to the field of semiconductor devices, and particularly relates to an enhanced GaN high electron mobility transistor (HEMT) radio-frequency device and a manufacturing method thereof.

### BACKGROUND

With the urgent demand for fifth-generation (5G) communication base stations for high-performance radio-frequency front ends, a high-frequency and low-loss GaN HEMT radio-frequency device has been widely researched. However, the conventional GaN HEMT radio-frequency device is a depletion device. For the depletion-mode GaN HEMT radio-frequency device, the gate driver circuit is complicated, and more passive components are provided in an integrated circuit (IC). This causes a serious signal loss of the GaN HEMT radio-frequency device, and is tricky to realize a high-frequency and low-loss miniaturized radio-frequency chip. Meanwhile, due to the on-state of a heterojunction trench in the depletion-mode GaN HEMT radio-frequency device, a gate is driven by a negative voltage in testing and use, thereby preventing a short circuit to cause an irreparable loss. Therefore, an enhanced radio-frequency device capable of making the circuit safer, simplifying design of the circuit and having lower power consumption is desired to realize a miniaturized radio-frequency chip with high safety, high frequency and low loss.

At present, the enhanced radio-frequency device is mainly realized by a recessed-gate technology. Specifically, a barrier layer beneath the gate is thinned by dry etching to reduce the polarization effect of the trench under the gate and deplete a two-dimensional electron gas (2DEG) trench, thus realizing the enhanced radio-frequency device. The recessed-gate technology has the advantages of a simple process, high threshold voltage, high gate driving voltage, etc. However, due to low electron mobility of the trench under the gate, this technology is hard to manufacture the radio-frequency device with a high-frequency. Meanwhile, because of a high density of defects caused by surface damage during recess etching, a loss of radio-frequency signals is increased, making a high-frequency and low-loss radio-frequency device hard to manufacture. An enhanced power device for a p-GaN gate cap layer structure has been put into commercial use. The p-GaN gate cap layer structure keeps the complete 2DEG trench, and does not require any gate dielectric, which is beneficial for realization of the high-frequency and low-loss radio-frequency device. However, there haven't been any reports on the radio-frequency device of the p-GaN gate cap layer structure. The conventional p-GaN gate cap layer structure is realized by performing dry etching on a p-GaN gate cap layer beyond the region under the gate, and is highly demanded for uniformity and accuracy of an etching device. Apparently, however, this technology is inapplicable for the manufacture of an enhanced radio-frequency device with a gate length of no more than 0.25 μm.

### SUMMARY

The present disclosure provides an enhanced GaN HEMT radio-frequency device, to overcome defects and shortages in the prior art.

Another objective of the present disclosure is to provide a manufacturing method of the enhanced GaN HEMT radio-frequency device.

### Technical Solution of the Problem

### Technical Solution

The present disclosure is achieved by the following technical solutions:

An enhanced GaN HEMT radio-frequency device sequentially includes a substrate, a first AlN interposed layer, a GaN buffer layer, a GaN trench layer, a second AlN interposed layer, and an AlGaN barrier layer from bottom to top, where the AlGaN barrier layer is a component gradual-changing layer; a metal drain electrode and a metal source electrode are arranged on the AlGaN barrier layer; the metal drain electrode and the metal source electrode are located on the AlGaN barrier layer; the metal drain electrode and the metal source electrode come in ohmic contact with the AlGaN barrier layer; a p-AlGaN layer is provided under a metal gate electrode; and the p-AlGaN layer is embedded into the AlGaN barrier layer, such that the metal gate electrode comes in Schottky contact with the AlGaN barrier layer.

Further, the first AlN interposed layer has a thickness of 100 nm.

Further, the GaN buffer layer has a thickness of 2-4 μm.

Further, the GaN trench layer has a thickness of 1-2 μm.

Further, the second AlN interposed layer has a thickness of 0.5-2 nm.

Further, the AlGaN barrier layer has a thickness of 5-50 nm.

Further, the metal gate electrode is a T-shaped gate structure.

A manufacturing method of the enhanced GaN HEMT radio-frequency device includes the following steps:
sequentially and epitaxially growing the first AlN interposed layer, the GaN buffer layer, the GaN trench layer, the second AlN interposed layer, and the AlGaN barrier layer on the substrate;
performing photoetching on an epitaxial wafer of the AlGaN barrier layer to expose a metal gate electrode region, evaporating metal Mg and a HfO₂ layer, and performing annealing to form the p-AlGaN layer, where the metal Mg forms a p-n junction with an undiffused AlGaN layer to effectively deplete a 2DEG under a gate, and the HfO₂ layer prevents oxidation of the metal Mg to obtain an enhanced radio-frequency device with a gate length of no more than 0.25 μm; and
manufacturing the source electrode, the drain electrode and the T-shaped metal gate electrode to obtain an enhanced GaN HEMT radio-frequency device.

Further, the p-AlGaN layer is formed as follows: spin-coating a negative photoresist for 10 μm on the epitaxial wafer of the AlGaN barrier layer, performing the photoetching with electron beam exposure to expose a region under the metal gate electrode, evaporating the metal Mg and the HfO₂ layer, and performing the annealing to form the p-AlGaN layer.

Further, the annealing is performed at 400-850° C. for 1-10 min.

Further, the drain electrode and the metal source electrode are formed by rapid annealing; and the rapid annealing is performed at 800-900° C. in the presence of N₂, heat preservation time being 10-60 s, and a heating rate being 10-20° C./s.

Further, the first AlN interposed layer, the second AlN interposed layer, the GaN trench layer and the AlGaN barrier layer are grown by metal organic chemical vapor deposition (MOCVD) at 850-950° C.

### Beneficial Effects of the Present Disclosure

### Beneficial Effects

The present disclosure has following beneficial effects:

(1) Under an extremely high vacuum degree, by doping and diffusing the metal Mg to the AlGaN layer under the gate to form the p-AlGaN layer, and allowing the metal Mg to form the p-n junction with an undiffused AlGaN layer, the present disclosure effectively depletes the 2DEG under the gate and prevents alloy scattering, thereby obtaining the enhanced GaN HEMT radio-frequency device with the gate length of no more than 0.25 μm.

(2) Under the extremely high vacuum degree, the evaporated metal Mg is covered by the HfO₂ layer, and the metal Mg is not oxidized. Therefore, the present disclosure improves a diffusion efficiency of the metal Mg, and is beneficial to realize the enhanced GaN HEMT radio-frequency device.

(3) The enhanced radio-frequency device is used more safely to protect the circuit. With the present disclosure, the gate driver circuit, the passive components are omitted, and the device has the lower power consumption. Therefore, the safe and low-loss miniaturized GaN HEMT radio-frequency device is realized.

### BRIEF DESCRIPTION OF THE DRAWINGS

### Description of Drawings

The FIGURE is a schematic structural view of an enhanced GaN HEMT radio-frequency device according to the present disclosure.

### DETAILED DESCRIPTION OF THE EMBODIMENTS

### Description of Embodiments

The present disclosure is further described below with reference to the embodiments and accompanying drawings, but the implementations of the present disclosure are not limited thereto.

### Embodiment 1

The FIGURE is a schematic structural view of an enhanced GaN HEMT radio-frequency device according to the embodiment. As shown in the FIGURE, the enhanced GaN HEMT radio-frequency device includes substrate 1, first AlN interposed layer 2, GaN buffer layer 3, GaN trench layer 4, second AlN interposed layer 5, AlGaN barrier layer 6, p-AlGaN layer 7, metal drain electrode 8, metal gate electrode 9, and metal source electrode 10.

The substrate 1, the first AlN interposed layer 2, the GaN buffer layer 3, the GaN trench layer 4, the second AlN interposed layer 5, and the AlGaN barrier layer 6 are sequentially stacked from bottom to top.

The p-AlGaN layer is located under the metal gate electrode 9.

The metal drain electrode 8 and the metal source electrode 10 are located on the AlGaN barrier layer 6. The metal drain electrode 8 and the metal source electrode 10 come in ohmic contact with the AlGaN barrier layer 6.

The metal gate electrode 9 is located on the AlGaN barrier layer 6. The metal gate electrode 9 comes in Schottky contact with the AlGaN barrier layer 6.

The enhanced GaN HEMT radio-frequency device in the embodiment is manufactured as follows:
Step 1: The first AlN interposed layer with a thickness of 100 nm is epitaxially grown by MOCVD at 850° C. on the silicon substrate.
Step 2: The GaN buffer layer is epitaxially grown by MOCVD at 850° C. on an epitaxial wafer obtained in Step 1.
Step 3: The GaN trench layer is epitaxially grown by MOCVD at 850° C. on an epitaxial wafer obtained in Step 2.
Step 4: The second AlN interposed layer is epitaxially grown by MOCVD at 850° C. on an epitaxial wafer obtained in Step 3.
Step 5: The AlGaN barrier layer is epitaxially grown by MOCVD at 850° C. on an epitaxial wafer obtained in Step 4.
Step 6: Photoetching is performed on an epitaxial wafer obtained in Step 5 to expose a metal gate electrode region. Metal Mg with a thickness of 100 nm and a HfO₂ layer with a thickness of 10 nm are evaporated. By this time, a vacuum degree is required to reach a limit of a device, and is usually 10-5 Pa. Annealing is performed at 550° C. for 2 min. A temperature is heated to 850° C., and preserved for 30 s. After lowered to 100° C. or below, the temperature is heated to 250° ° C. and preserved for 1 min.
Step 7: Photoetching is performed on an epitaxial wafer obtained in Step 6 to expose a metal source electrode region and a metal drain electrode region. Metal Ti/Al/Ni/Au is evaporated and subjected to stripping and annealing to form the metal source electrode and the metal drain electrode. Specifically, the annealing is performed at 800° C. in the presence of N₂, heat preservation time being 40 s, and a heating rate being 15° C./s.
Step 8: Photoetching is performed on an epitaxial wafer obtained in Step 7 to expose the metal gate electrode region. Metal Ni/Au is evaporated and subjected to stripping to form the metal gate electrode with a gate length of 50 nm, thereby obtaining the final enhanced radio-frequency device.

The direct-current (DC) characteristic and radio-frequency performance of the device obtained in Step 8 are tested with a semiconductor analyzer and a vector network analyzer (VNA). Consequently, a threshold voltage is 1.5 V, an on resistance is 300 mΩ, a breakdown voltage is 200 V, a working frequency is 30 GHz, a power gain is 10 dB, and a power-added efficiency (PAE) is 54%.

A circuit is provided for the well-tested device obtained in Step 8. The original negative-voltage driver circuit is omitted, the whole circuit is simpler, and the device is a lower power consumption. In the whole system testing, the testing procedures are simplified, and the device is safer in use and testing to protect the circuit.

### Embodiment 2

The FIGURE is a schematic structural view of an enhanced GaN HEMT radio-frequency device according to the embodiment. The enhanced GaN HEMT radio-frequency device includes substrate 1, first AlN interposed layer 2, GaN buffer layer 3, GaN trench layer 4, second AlN interposed layer 5, AlGaN barrier layer 6, p-AlGaN layer 7, metal drain electrode 8, metal gate electrode 9, and metal source electrode 10.

The substrate 1, the first AlN interposed layer 2, the GaN buffer layer 3, the GaN trench layer 4, the second AlN interposed layer 5, and the AlGaN barrier layer 6 are sequentially stacked from bottom to top.

The p-AlGaN layer 7 is located under the metal gate electrode 9.

The metal drain electrode 8 and the metal source electrode 10 are located on the AlGaN barrier layer 6. The metal drain electrode 8 and the metal source electrode 10 come in ohmic contact with the AlGaN barrier layer 6.

The metal gate electrode 9 is located on the AlGaN barrier layer 6. The metal gate electrode 9 comes in Schottky contact with the AlGaN barrier layer 6.

The enhanced GaN HEMT radio-frequency device in the embodiment is manufactured as follows:
Step 1: The first AlN interposed layer with a thickness of 100 nm is epitaxially grown by MOCVD at 850° C. on the silicon substrate.
Step 2: The GaN buffer layer is epitaxially grown by MOCVD at 850° C. on an epitaxial wafer obtained in Step 1.
Step 3: The GaN trench layer is epitaxially grown by MOCVD at 850° C. on an epitaxial wafer obtained in Step 2.
Step 4: The second AlN interposed layer is epitaxially grown by MOCVD at 850° ° C. on an epitaxial wafer obtained in Step 3.
Step 5: The AlGaN barrier layer is epitaxially grown by MOCVD at 850° C. on an epitaxial wafer obtained in Step 4.
Step 6: Photoetching is performed on an epitaxial wafer obtained in Step 5 to expose a metal gate electrode region. Metal Mg with a thickness of 50 nm and a HfO₂ layer with a thickness of 30 nm are evaporated. By this time, a vacuum degree is required to reach a limit of a device, and is usually 10-5 Pa. Annealing is performed at 600° C. for 5 min. A temperature is heated to 800° C., and preserved for 1 min. After lowered to 150° C. or below, the temperature is heated to 300° C., and preserved for 2 min.
Step 7: Photoetching is performed on an epitaxial wafer obtained in Step 6 to expose a metal source electrode region and a metal drain electrode region. Metal Ti/Al/Ni/Au is evaporated and subjected to stripping and annealing to form the metal source electrode and the metal drain electrode. Specifically, the annealing is performed at 850° C. in the presence of N₂, heat preservation time being 30 s, and a heating rate being 15° ° C./s.
Step 8: Photoetching is performed on an epitaxial wafer obtained in Step 7 to expose the metal gate electrode region. Metal Ni/Au is evaporated and subjected to stripping to form the metal gate electrode with a gate length of 150 nm, thereby obtaining the final enhanced radio-frequency device.

The DC characteristic and radio-frequency performance of the device obtained in Step 8 are tested with a semiconductor analyzer and a VNA. Consequently, a threshold voltage is 1.3 V, an on resistance is 300 mΩ, a breakdown voltage is 200 V, a working frequency is 25 GHz, a power gain is 12 dB, and a PAE is 62%.

A circuit is provided for the well-tested device obtained in Step 8. The original negative-voltage driver circuit is omitted, the whole circuit is simpler, and the device is a lower power consumption. In the whole system testing, the testing procedures are simplified, and the device is safer in use and testing to protect the circuit.

### Embodiment 3

The FIGURE is a schematic structural view of an enhanced GaN HEMT radio-frequency device according to the embodiment. The enhanced GaN HEMT radio-frequency device includes substrate 1, first AlN interposed layer 2, GaN buffer layer 3, GaN trench layer 4, second AlN interposed layer 5, AlGaN barrier layer 6, p-AlGaN layer 7, metal drain electrode 8, metal gate electrode 9, and metal source electrode 10.

The substrate 1, the first AlN interposed layer 2, the GaN buffer layer 3, the GaN trench layer 4, the second AlN interposed layer 5, and the AlGaN barrier layer 6 are sequentially stacked from bottom to top.

The p-AlGaN layer is located under the metal gate electrode 9.

The metal drain electrode 8 and the metal source electrode 10 are located on the AlGaN barrier layer 6. The metal drain electrode 8 and the metal source electrode 10 come in ohmic contact with the AlGaN barrier layer 6.

The metal gate electrode 9 is located on the AlGaN barrier layer 6. The metal gate electrode 9 comes in Schottky contact with the AlGaN barrier layer 6.

The enhanced GaN HEMT radio-frequency device in the embodiment is manufactured as follows:
Step 1: The first AlN interposed layer with a thickness of 100 nm is epitaxially grown by MOCVD at 850° C. on the silicon substrate.
Step 2: The GaN buffer layer is epitaxially grown by MOCVD at 850° C. on an epitaxial wafer obtained in Step 1.
Step 3: The GaN trench layer is epitaxially grown by MOCVD at 850° C. on an epitaxial wafer obtained in Step 2.
Step 4: The second AlN interposed layer is epitaxially grown by MOCVD at 850° C. on an epitaxial wafer obtained in Step 3.
Step 5: The AlGaN barrier layer is epitaxially grown by MOCVD at 850° C. on an epitaxial wafer obtained in Step 4.
Step 6: Photoetching is performed on an epitaxial wafer obtained in Step 5 to expose a metal gate electrode region. Metal Mg with a thickness of 200 nm and a HfO₂ layer with a thickness of 100 nm are evaporated. By this time, a vacuum degree is required to reach a limit of a device, and is usually 10-5 Pa. Annealing is performed at 650° ° C. for 10 min. A temperature is heated to 900° C., and preserved for 5 min. After lowered to 100° C. or below, the temperature is heated to 200° C., and preserved for 30 s.
Step 7: Photoetching is performed on an epitaxial wafer obtained in Step 6 to expose a metal source electrode region and a metal drain electrode region. Metal Ti/Al/Ni/Au is evaporated and subjected to stripping and annealing to form the metal source electrode and the metal drain electrode. Specifically, the annealing is performed at 900° C. in the presence of N₂, heat preservation time being 20 s, and a heating rate being 15° C./s.
Step 8: Photoetching is performed on an epitaxial wafer obtained in Step 7 to expose the metal gate electrode region. Metal Ni/Au is evaporated and subjected to stripping to form the metal gate electrode with a gate length of 250 nm, thereby obtaining the final enhanced radio-frequency device.

The DC characteristic and radio-frequency performance of the device obtained in Step 8 are tested with a semiconductor analyzer and a VNA. Consequently, a threshold voltage is 1.7 V, an on resistance is 300 mΩ, a breakdown voltage is 250 V, a working frequency is 18 GHz, a power gain is 15 dB, and a PAE is 71%.

A circuit is provided for the well-tested device obtained in Step 8. The original negative-voltage driver circuit is omitted, the whole circuit is simpler, and the device is a lower power consumption. In the whole system testing, the testing procedures are simplified, and the device is safer in use and testing to protect the circuit.

The present disclosure manufactures the enhanced high-frequency and low-loss radio-frequency device by doping and diffusing Mg to the gradual-changing AlGaN barrier layer. The metal Mg is easily doped in the top of the AlGaN layer due to a small content of the Al component, and the metal Mg is not diffused to the 2DEG trench in the bottom of the layer due to a high content of the Al component. This causes serious alloy scattering to reduce a frequency characteristic of the device. The metal Mg with a gate length of no more than 0.25 μm is easily oxidized into MgO in evaporation and stripping, and hardly doped to the AlGaN barrier layer. Therefore, by evaporating the Mg and then covering the HfO₂ layer, the metal Mg is not oxidized in the stripping and other processes. Meanwhile, the HfO₂ layer can further serve as a gate dielectric. This is vital to suppress the current collapse of the device.

The above embodiments are preferred implementations of the present disclosure, but the implementations of the present disclosure are not limited to these embodiments, and any other changes, modifications, substitutions, combinations and simplifications made without departing from the spirit and principle of the present disclosure shall be equivalent replacement means, and shall be included in the protection scope of the present disclosure.

What is claimed is:

1. An enhanced GaN high electron mobility transistor (HEMT) radio-frequency device, sequentially comprising a substrate, a first AlN interposed layer, a GaN buffer layer, a GaN trench layer, a second AlN interposed layer, and an AlGaN barrier layer from bottom to top,
wherein a metal drain electrode and a metal source electrode are arranged on the AlGaN barrier layer; the metal drain electrode and the metal source electrode come in ohmic contact with the AlGaN barrier layer; a p-AlGaN layer is provided under a metal gate electrode; and the p-AlGaN layer is embedded into the AlGaN barrier layer, wherein the metal gate electrode comes in Schottky contact with the AlGaN barrier layer.

2. The enhanced GaN HEMT radio-frequency device according to claim 1, wherein the GaN trench layer has a thickness of 1-2 μm.

3. The enhanced GaN HEMT radio-frequency device according to claim 1, wherein the second AlN interposed layer has a thickness of 0.5-2 nm.

4. The enhanced GaN HEMT radio-frequency device according to claim 1, wherein the AlGaN barrier layer has a thickness of 5-50 nm.

5. The enhanced GaN HEMT radio-frequency device according to claim 1, wherein the metal gate electrode is a T-shaped gate structure.

6. A manufacturing method of the enhanced GaN HEMT radio-frequency device according to claim 1, comprising:
sequentially and epitaxially growing the first AlN interposed layer, the GaN buffer layer, the GaN trench layer, the second AlN interposed layer, and the AlGaN barrier layer on the substrate;
performing photoetching on an epitaxial wafer of the AlGaN barrier layer to expose a metal gate electrode region, evaporating metal Mg and a HfO₂ layer, and performing annealing to form the p-AlGaN layer, wherein the metal Mg forms a p-n junction with an undiffused AlGaN layer to effectively deplete a two-dimensional electron gas (2DEG) under a gate, thereby obtaining an enhanced radio-frequency device with a gate length of no more than 0.25 μm; and
manufacturing the metal source electrode, the metal drain electrode and the T-shaped metal gate electrode.

7. The manufacturing method according to claim 6, wherein the p-AlGaN layer is formed as follows: spin-coating a negative photoresist for 10 μm on the epitaxial wafer of the AlGaN barrier layer, performing the photoetching with electron beam exposure to expose a region under the metal gate electrode, evaporating the metal Mg and the HfO₂ layer, and performing the annealing to form the p-AlGaN layer.

8. The manufacturing method according to claim 7, wherein the annealing is performed at 400-850° C. for 1-10 min.

9. The manufacturing method according to claim 6, wherein the metal drain electrode and the metal source electrode are formed by rapid annealing; and the rapid annealing is performed at 800-900° C. in a presence of N₂, a heat preservation time being 10-60 s, and a heating rate being 10-20° C./s.

10. The manufacturing method according to claim 6, wherein the first AlN interposed layer, the second AlN interposed layer, the GaN trench layer and the AlGaN barrier layer are grown by metal organic chemical vapor deposition (MOCVD) at 850-950° C.

11. The manufacturing method according to claim 6, wherein in the enhanced GaN HEMT radio-frequency device, the GaN trench layer has a thickness of 1-2 μm.

12. The manufacturing method according to claim 6, wherein in the enhanced GaN HEMT radio-frequency device, the second AlN interposed layer has a thickness of 0.5-2 nm.

13. The manufacturing method according to claim 6, wherein in the enhanced GaN HEMT radio-frequency device, the AlGaN barrier layer has a thickness of 5-50 nm.

14. The manufacturing method according to claim 6, wherein in the enhanced GaN HEMT radio-frequency device, the metal gate electrode is a T-shaped gate structure.
